(19) United States
(12) Patent Application Publication
(10) Pub. No.: US 2026/0154481 A1
(43) Pub. Date: Jun. 4, 2026

(54) NOZZLE DESIGN METHOD

(71) Applicant: METAL INDUSTRIES RESEARCH & DEVELOPMENT CENTRE, KAOHSIUNG (TW)

(72) Inventors: Fu-Chuan HSU, Kaohsiung City (TW); Shang-You ZHAN, Chiayi County (TW); Meng-Hsiu TSAI, Kaohsiung City (TW); Yun-Jie HONG, Tainan City (TW); Yi-Cheng CHEN, Tainan City (TW); Ho-Chung FU, KAOHSIUNG CITY (TW)

(21) Appl. No.: 19/321,312

(22) Filed: Sep. 8, 2025

(30) Foreign Application Priority Data
Dec. 4, 2024 (TW) 113146988

(51) Int. Cl. G06F 30/28

(52) U.S. Cl. CPC G06F 30/28

(57) ABSTRACT

A nozzle design method is suitable for designing a nozzle for particle surface modification, which includes a constriction section, a throat section, and a diffusion section connected sequentially. In this method, a CFD-DEM software is used to simulate at least one nozzle size set in a particle velocity range to obtain first to third coefficient ranges and a constant range of a nozzle size design equation. The nozzle size design equation is V=a*X+b*Y+c*Z+d, wherein V is a particle velocity, a, b, and c are first to third coefficients respectively, d is a constant, X, Y, and Z are maximum flow channel diameters of the constriction section, the throat section, and the diffusion section respectively. The CFD-DEM software is used to calculate through the nozzle size design equation with the first to third coefficient ranges and the constant range, and a target velocity to obtain a calculated nozzle size set.

### CROSS-REFERENCE TO RELATED APPLICATIONS

This application claims priority to Taiwan Application Serial Number 113146988, filed Dec. 4, 2024, which is herein incorporated by reference in its entirety.

### BACKGROUND

### Field of Invention

The present disclosure relates to a particle surface modification technology, and more particularly, to a nozzle design method.

### Description of Related Art

A particle surface modification technology uses particles to impact a surface of a workpiece to increase the strength and the hardness of the surface of the workpiece and enhance the wear resistance and the lubricity of the surface of the workpiece, thereby increasing the service life of the workpiece. The jet velocity of the particles will affect the surface roughness of the workpiece, and thus affecting the surface modification effect of the workpiece.

Related technical literatures show that the size design of the nozzle has a significant impact on the jet velocity of the particles. Therefore, the size design of the nozzle for particle surface modification has become a critical link in the development of particle surface modification technology.

### SUMMARY

One objective of the present disclosure is to provide a nozzle design method, which uses a coupled simulation technology of a computational fluid dynamics-discrete element method (CFD-DEM) software to simulate the interaction between airflow and particles with different geometric parameters of the nozzle to obtain the nozzle size design equation. The nozzle size design equation allows for quick iteration to design the nozzle size, such that the time cost of experiments and adjustments during the design of the nozzle can be reduced, and the efficiency of the nozzle in industrial applications can be enhanced. In addition, the present method can accurately predict the velocity of the particles under different nozzle diameter combinations, thereby greatly enhancing the efficiency and the accuracy of the design of the nozzle 100.

Another objective of the present disclosure is to provide a nozzle design method, which can adjust the size of the nozzle in real time according to the velocity of the particles, such that it can adapt to different operation requirements and material properties to ensure the best ejecting effect of the nozzle.

According to the aforementioned objectives, the present disclosure provides a nozzle design method, which is suitable for designing a nozzle for particle surface modification. The nozzle for particle surface modification includes a constriction section, a throat section, and a diffusion section that are connected in sequence. In this method, a computational fluid dynamics-discrete element method software is used to simulate at least one nozzle size set in a particle velocity range to obtain a first coefficient range, a second coefficient range, a third coefficient range, and a constant range of a nozzle size design equation. Each nozzle size set includes a maximum flow channel diameter of the constriction section, a maximum flow channel diameter of the throat section, and a maximum flow channel diameter of the diffusion section. The nozzle size design equation is V=a*X+b*Y+c*Z+d, in which V represents a particle velocity, a, b, and c respectively represent a first coefficient, a second coefficient, and a third coefficient, d represents a constant, X represents the maximum flow channel diameter of the constriction section, Y represents the maximum flow channel diameter of the throat section, and Z represents the maximum flow channel diameter of the diffusion section. The computational fluid dynamics-discrete element method software is used to calculate through the nozzle size design equation with the first coefficient range, the second coefficient range, the third coefficient range, the constant range, and a target velocity to obtain a calculated nozzle size set.

According to one embodiment of the present disclosure, the particle velocity range is ranging from a selected particle velocity minus 5% of the selected particle velocity to the selected particle velocity plus 5% of the selected particle velocity.

According to one embodiment of the present disclosure, using the computational fluid dynamics-discrete element method software to simulate the at least one nozzle size set in the particle velocity range includes using a linear equation iteration method.

According to one embodiment of the present disclosure, the at least one nozzle size set includes a first nozzle size set. In the first nozzle size set, the maximum flow channel diameter of the constriction section is 14 mm, the maximum flow channel diameter of the throat section is 7 mm, and the maximum flow channel diameter of the diffusion section is 9 mm.

According to one embodiment of the present disclosure, the at least one nozzle size set further includes a second nozzle size set. In the second nozzle size set, the maximum flow channel diameter of the constriction section is 11 mm, the maximum flow channel diameter of the throat section is 4 mm, and the maximum flow channel diameter of the diffusion section is 6 mm.

According to one embodiment of the present disclosure, the at least one nozzle size set further includes a third nozzle size set. In the third nozzle size set, the maximum flow channel diameter of the constriction section is 17 mm, the maximum flow channel diameter of the throat section is 10 mm, and the maximum flow channel diameter of the diffusion section is 12 mm.

According to one embodiment of the present disclosure, the first coefficient range is from 20 to 100, the second coefficient range is from −100 to 200, the third coefficient range is from −1 to 20, and the constant range is from 400 to 1300.

According to one embodiment of the present disclosure, after obtaining the calculated nozzle size set, the nozzle design method further includes using the computational fluid dynamics-discrete element method software to simulate the calculated nozzle size set to obtain a simulated velocity. An error between the target velocity and the simulated velocity is equal to or smaller than 5%.

According to one embodiment of the present disclosure, using the computational fluid dynamics-discrete element method software to calculate through the nozzle size design equation with the first coefficient range, the second coefficient range, the third coefficient range, the constant range, and the target velocity includes using a linear equation iteration method.

According to one embodiment of the present disclosure, a length of the constriction section of the nozzle for particle surface modification is 12 mm, a length L2 of the throat section is 19 mm, and a length of the diffusion section is 5 mm.

### BRIEF DESCRIPTION OF THE DRAWINGS

Aspects of the present disclosure are best understood from the following detailed description in conjunction with the accompanying figures. It is noted that in accordance with the standard practice in the industry, various features are not drawn to scale. In fact, dimensions of the various features can be arbitrarily increased or reduced for clarity of discussion.

FIG. 1 is a schematic side view of a nozzle in accordance with an embodiment of the present disclosure.

FIG. 2 is a schematic flow chart of a nozzle design method in accordance with an embodiment of the present disclosure.

### DETAILED DESCRIPTION

The embodiments of the present disclosure are discussed in detail below. However, it will be appreciated that the embodiments provide many applicable concepts that can be implemented in various specific contents. The embodiments discussed and disclosed are for illustrative purposes only and are not intended to limit the scope of the present disclosure. All of the embodiments of the present disclosure disclose various different features, and these features may be implemented separately or in combination as desired.

In addition, the terms “first”, “second”, and the like, as used herein, are not intended to mean a sequence or order, and are merely used to distinguish elements or operations described in the same technical terms.

The spatial relationship between two elements described in the present disclosure applies not only to the orientation depicted in the drawings, but also to the orientations not represented by the drawings, such as the orientation of the inversion. Moreover, the terms “connected”, “electrically connected”, or the like between two components referred to in the present disclosure are not limited to the direct connection or electrical connection of the two components, and may also include indirect connection or electrical connection as required.

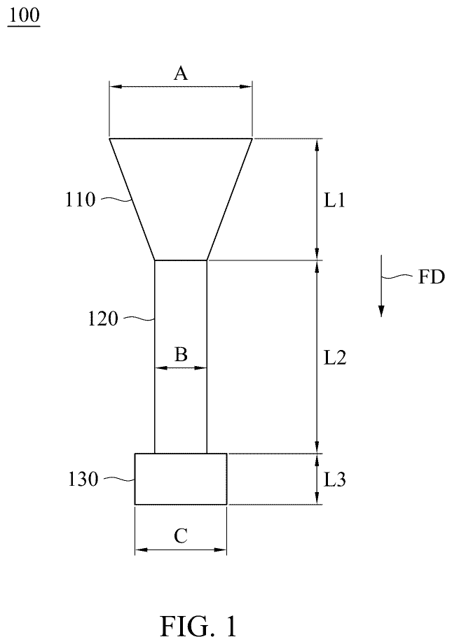

Referring to FIG. 1, FIG. 1 is a schematic side view of a nozzle 100 in accordance with an embodiment of the present disclosure. The nozzle 100 is a nozzle for particle surface modification. The nozzle 100 may be used to eject particles onto a surface of a workpiece, so as to utilize the bombardment of the particles on the surface of the workpiece to perform a surface modification treatment on the workpiece. The nozzle 100 may mainly include a constriction section 110, a throat section 120, and a diffusion section 130. The constriction section 110, the throat section 120, and the diffusion section 130 are sequentially connected to form the nozzle 100. Specifically, two opposite ends of the throat section 120 are respectively connected to one end of the constriction section 110 and one end of the diffusion section 130, such that the throat section 120 is sandwiched between the constriction section 110 and the diffusion section 130.

The gas and the particles enter the nozzle 100 from the constriction section 110, pass through the throat section 120 along a flow direction FD of the gas and the particles, and then are ejected out of the nozzle 100 from the diffusion section 130. In some examples, in the flow direction FD, a flow channel of the constriction section 110 gradually decreases, and a flow channel of the diffusion section 130 gradually increases. In the present embodiment, a cross-sectional shape of each of the flow channels of the constriction section 110, the throat section 120, and the diffusion section 130 is circular. The constriction section 110 has a maximum flow channel diameter A, the throat section 120 has a maximum flow channel diameter B, and the diffusion section 130 has a maximum flow channel diameter C. In addition, the constriction section 110 has a length L1, the throat section 120 has a length L2, and the diffusion section 130 has a length L3.

The size design of the constriction section 110 is extremely important for the control of the gas intake amount of the nozzle 100. The throat section 120 is a key part for the control of the gas flow rate and is extremely important for increasing the gas velocity, and the diameter and the length of the throat section 120 need to match the size design of the constriction section 110 and the diffusion section 130. The diffusion section 130 can reduce the gas pressure to stabilize and increase the injection kinetic energy of the particles. The design should consider the smooth transition of the fluid through the diffusion section 130 to prevent turbulence. By optimizing the geometry of the nozzle 100 and precisely controlling the length and the diameter of each section of the nozzle 100, it can ensure that the airflow is stably accelerated in the nozzle 100 to prevent turbulence, and further to increase the ejection kinetic energy of the particles.

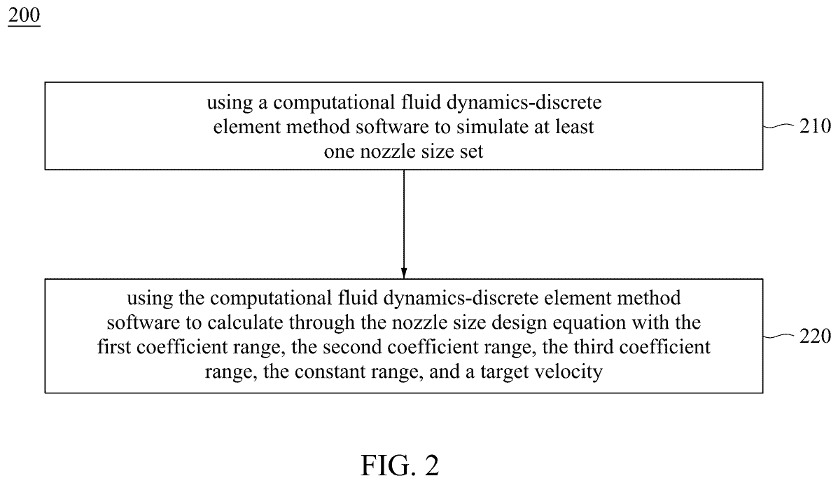

Referring to FIG. 1 and FIG. 2 simultaneously, FIG. 2 is a schematic flow chart of a nozzle design method 200 in accordance with an embodiment of the present disclosure. The nozzle design method 200 may be used to design the aforementioned nozzle 100 for particle surface modification. In the present embodiment, the nozzle design method 200 is performed under the condition that the length L1 of the constriction section 110, the length L2 of the throat section 120, and the length L3 of the diffusion section 130 of the nozzle 100 are fixed. In some examples, the length L1 of the constriction section 110 is 12 mm, the length L2 of the throat section 120 is 19 mm, and the length L3 of the diffusion section 130 is 5 mm.

When the nozzle design method 200 is used to design the nozzle 100, a step 210 may be first performed to use a computational fluid dynamics-discrete element method (CFD-DEM) software to simulate at least one nozzle size set. The computational fluid dynamics-discrete element method software can simulate gas-solid two-phase flow and the movement trajectory of the airflow and the particles. Each nozzle size set includes the maximum flow channel diameter A of the constriction section 110, the maximum flow channel diameter B of the throat section 120, and the maximum flow channel diameter C of the diffusion section 130. In the step 210, each nozzle size set is simulated in a particle velocity range. For example, the particle velocity range may be ranging from a selected particle velocity minus 5% of the selected particle velocity to the selected particle velocity plus 5% of the selected particle velocity. The selected particle velocity may be ranging from 200 mm/s to 1400 mm/s. However, the particle velocity range may be any velocity within a range of 200 mm/s to 1400 mm/s, and the present disclosure is not limited thereto.

After using the computational fluid dynamics-discrete element method software to simulate the at least one nozzle size set, a first coefficient range, a second coefficient range, a third coefficient range, and a constant range of a nozzle size design equation can be obtained. The nozzle size design equation is expressed as V=a*X+b*Y+c*Z+d. V represents a particle velocity, a, b, and c respectively represent a first coefficient, a second coefficient, and a third coefficient, d represents a constant, X represents the maximum flow channel diameter of the constriction section, Y represents the maximum flow channel diameter of the throat section, and Z represents the maximum flow channel diameter of the diffusion section. The first coefficient range, the second coefficient range, the third coefficient range, and the constant range are numerical ranges of the first coefficient, the second coefficient, the third coefficient, and the constant, respectively. In some examples, when using the CFD-DEM software to simulate the nozzle size set, a linear equation iteration method is used.

In some examples, the at least one nozzle size set includes a first nozzle size set. In the first nozzle size set, the maximum flow channel diameter A of the constriction section 110 is 14 mm, the maximum flow channel diameter B of the throat section 120 is 7 mm, and the maximum flow channel diameter C of the diffusion section 130 is 9 mm. In some other examples, in addition to the first nozzle size set, the at least one nozzle size set further includes a second nozzle size set. In the second nozzle size set, the maximum flow channel diameter A of the constriction section 110 is 11 mm, the maximum flow channel diameter B of the throat section 120 is 4 mm, and the maximum flow channel diameter C of the diffusion section 130 is 6 mm. In some further examples, the at least one nozzle size set further includes a third nozzle size set. In the third nozzle size set, the maximum flow channel diameter A of the constriction section 110 is 17 mm, the maximum flow channel diameter B of the throat section 120 is 10 mm, and the maximum flow channel diameter C of the diffusion section 130 is 12 mm.

In the example of simulating the aforementioned first to third nozzle size sets, the first coefficient of the nozzle size design equation obtained through the simulation by the computational fluid dynamics-discrete element method software ranges from 20 to 100, the second coefficient ranges from −100 to 200, the third coefficient ranges from −1 to 20, and the constant ranges from 400 to 1300. Thus, the nozzle size design equation is V=(20˜100)*X+(−100˜200)*Y+(−1˜20)*Z+(400˜1300).

It is worth noting that the first coefficient range, the second coefficient range, the third coefficient range, and the constant range of the nozzle size design equation obtained by simulating different nozzle size sets using the computational fluid dynamics-discrete element method software may be different from those in the above-mentioned example. When the computational fluid dynamics-discrete element method software simulates more nozzle size sets, the accuracy of the first coefficient range, the second coefficient range, the third coefficient range, and the constant range of the nozzle size design equation can be enhanced.

After the first coefficient range, the second coefficient range, the third coefficient range, and the constant range of the nozzle size design equation are obtained, a step 220 may be performed to use the computational fluid dynamics-discrete element method software to calculate through the nozzle size design equation with the first coefficient range, the second coefficient range, the third coefficient range, the constant range, and a target velocity to obtain a calculated nozzle size set. Specifically, the computational fluid dynamics-discrete element method software substitutes the target velocity into the nozzle size design equation V=(20˜100)*X+(−100˜200)*Y+(−1˜20)*Z+(400˜1300) and performs simulation calculations to obtain the calculated nozzle size set. The calculated nozzle size set includes the calculated maximum flow channel diameter of the constriction section, the maximum flow channel diameter of the throat section, and the maximum flow channel diameter of the diffusion section. That is, the simulation calculations can obtain X, Y, and Z in the nozzle size design equation. In some examples, performing the simulation calculations includes using a linear equation iteration method.

The target velocity of the particles ejected from the nozzle 100 can be obtained according to the requirements of the particle surface modification. For example, the requirements of the particle surface modification may include particle coverage, surface roughness, and mechanical properties such as surface hardness, tensile strength, and residual stress. At the target velocity, the computational fluid dynamics-discrete element method software can simulate and calculate the maximum flow channel diameters of the constriction section 110, the throat section 120, and the diffusion section 130 of the nozzle 100 corresponding to the target velocity through the nozzle size design equation V=(20˜100)*X+(−100˜200)*Y+(−1˜20)*Z+(400˜1300).

After calculating the maximum flow channel diameter of the contraction section, the maximum flow channel diameter of the throat section, and the maximum flow channel diameter of the diffusion section in the step 220, the surface coverage of the particles ejected from the nozzle 100 may be simulated by using the computational fluid dynamics-discrete element method software. In addition, the designed nozzle 100 can be used to actually conduct particle ejecting experiments. Thus, the design effect including surface coverage, surface roughness, and mechanical properties such as hardness, tensile strength, and surface residual stress of the nozzle 100 is verified. Furthermore, the simulation parameters can be adjusted and optimized based on the verification results to enhance the accuracy of the design result.

The nozzle design method 200 of the present embodiment uses a coupled simulation technology of the computational fluid dynamics-discrete element method software to simulate the interaction between the airflow and the particles with different geometric parameters of the nozzle 100 to obtain the nozzle size design equation. The nozzle size design equation allows for quick iteration to design the nozzle size, such that the time cost of experiments and adjustments during the design of the nozzle 100 can be reduced, and the efficiency of the nozzle 100 in industrial applications can be enhanced. In addition, the present method can accurately predict the velocity of the particles under different nozzle diameter combinations, thereby greatly enhancing the efficiency and the accuracy of the design of the nozzle 100. Furthermore, the nozzle design method 200 can adjust the size of the nozzle 100 in real time according to the velocity of the particles, such that it can adapt to different operation requirements and material properties to ensure the best ejecting effect of the nozzle 100.

The embodiments of the present disclosure are based on a comprehensive method of numerical simulation and experimental verification, which can predict and optimize the design of the nozzle 100, such that the best ejecting effect of the particles can be achieved. Thus, the coverage range, the surface roughness, and the mechanical properties of the particle surface modification can be improved. By optimizing the sizes of the nozzle 100, the gas pressure limitation of the machine can be overcome, and a higher gas flow velocity and particle acceleration effect can be achieved under lower gas pressure parameters. Therefore, the velocity of the particles can be effectively increased without increasing the gas pressure or energy consumption, such that the impact force of the ejected particles can be increased, and the surface modification time such as strengthening and polishing can be decreased, thereby enhancing the processing efficiency. In addition, faster particle ejection velocity means that processing can be completed in a shorter time, such that the energy consumption of the apparatus operation can be reduced, thereby enhancing energy utilization. The optimized design of the velocity of the nozzle 100 can enhance the particle treatment effect to achieve a higher coverage rate and a better surface treatment effect, thereby greatly enhancing the durability and the performance of the surface of the workpiece.

Although the present disclosure has been disclosed above with embodiments, it is not intended to limit the present disclosure. Any person having ordinary skill in the art can make various changes and modifications without departing from the spirit and scope of the present disclosure. Therefore, the protection scope of the present disclosure should be defined by the scope of the appended claims.

What is claimed is:

1. A nozzle design method suitable for designing a nozzle for particle surface modification, wherein the nozzle for particle surface modification comprises a constriction section, a throat section, and a diffusion section that are connected in sequence, and the nozzle design method comprises:
using a computational fluid dynamics-discrete element method (CFD-DEM) software to simulate at least one nozzle size set in a particle velocity range to obtain a first coefficient range, a second coefficient range, a third coefficient range, and a constant range of a nozzle size design equation, wherein each of the at least one nozzle size set comprises a maximum flow channel diameter of the constriction section, a maximum flow channel diameter of the throat section, and a maximum flow channel diameter of the diffusion section, and the nozzle size design equation is V=a*X+b*Y+c*Z+d, wherein V represents a particle velocity, a, b, and c respectively represent a first coefficient, a second coefficient, and a third coefficient, d represents a constant, X represents the maximum flow channel diameter of the constriction section, Y represents the maximum flow channel diameter of the throat section, and Z represents the maximum flow channel diameter of the diffusion section; and
using the computational fluid dynamics-discrete element method software to calculate through the nozzle size design equation with the first coefficient range, the second coefficient range, the third coefficient range, the constant range, and a target velocity to obtain a calculated nozzle size set.

2. The nozzle design method of claim 1, wherein the particle velocity range is ranging from a selected particle velocity minus 5% of the selected particle velocity to the selected particle velocity plus 5% of the selected particle velocity.

3. The nozzle design method of claim 1, wherein using the computational fluid dynamics-discrete element method software to simulate the at least one nozzle size set in the particle velocity range comprises using a linear equation iteration method.

4. The nozzle design method of claim 1, wherein the at least one nozzle size set comprises a first nozzle size set, and in the first nozzle size set, the maximum flow channel diameter of the constriction section is 14 mm, the maximum flow channel diameter of the throat section is 7 mm, and the maximum flow channel diameter of the diffusion section is 9 mm.

5. The nozzle design method of claim 4, wherein the at least one nozzle size set further comprises a second nozzle size set, and in the second nozzle size set, the maximum flow channel diameter of the constriction section is 11 mm, the maximum flow channel diameter of the throat section is 4 mm, and the maximum flow channel diameter of the diffusion section is 6 mm.

6. The nozzle design method of claim 5, wherein the at least one nozzle size set further comprises a third nozzle size set, and in the third nozzle size set, the maximum flow channel diameter of the constriction section is 17 mm, the maximum flow channel diameter of the throat section is 10 mm, and the maximum flow channel diameter of the diffusion section is 12 mm.

7. The nozzle design method of claim 6, wherein the first coefficient range is from 20 to 100, the second coefficient range is from −100 to 200, the third coefficient range is from −1 to 20, and the constant range is from 400 to 1300.

8. The nozzle design method of claim 1, wherein after obtaining the calculated nozzle size set, the nozzle design method further comprises using the computational fluid dynamics-discrete element method software to simulate the calculated nozzle size set to obtain a simulated velocity, and an error between the target velocity and the simulated velocity is equal to or smaller than 5%.

9. The nozzle design method of claim 1, wherein using the computational fluid dynamics-discrete element method software to calculate through the nozzle size design equation with the first coefficient range, the second coefficient range, the third coefficient range, the constant range, and the target velocity comprises using a linear equation iteration method.

10. The nozzle design method of claim 1, wherein a length of the constriction section of the nozzle for particle surface modification is 12 mm, a length L2 of the throat section is 19 mm, and a length of the diffusion section is 5 mm.
